(19) United States
(12) Patent Application Publication
(10) Pub. No.: US 2025/0251201 A1
(43) Pub. Date: Aug. 7, 2025

(54) FIXING STRUCTURE

(71) Applicant: FIVEGRAND INTERNATIONAL CO., LTD., New Taipei City (TW)

(72) Inventor: TING-JUI WANG, New Taipei City (TW)

(73) Assignee: FIVEGRAND INTERNATIONAL CO., LTD., New Taipei City (TW)

(21) Appl. No.: 19/001,534

(22) Filed: Dec. 25, 2024

(30) Foreign Application Priority Data
Feb. 2, 2024 (TW) 113104261

(51) Int. Cl. F28F 9/007; H05K 7/20

(52) U.S. Cl. CPC F28F 9/0075; H05K 7/2039

(57) ABSTRACT

The present disclosure provides a fixing structure that fastens a non-planar plate, a plate, a plate with non-uniform thickness and an object by an elastic fastener, and a method of use thereof. Thus, the fixing structure and the method of use thereof of the present disclosure are capable of quickly removing or mounting a non-planar plate, a plate or a plate with non-uniform thickness at an object in an effort-saving manner.

### CROSS-REFERENCE TO RELATED APPLICATION

This non-provisional application claims priority under 35 U.S.C. § 119(a) on Patent Application No(s). 113104261 filed in Taiwan, R.O.C. on Feb. 2, 2024, the entire contents of which are hereby incorporated by reference.

### BACKGROUND OF THE INVENTION

### 1. Field of the Invention

The present disclosure relates to a fixing structure and a method of use thereof, and in particular to a fixing structure for a non-planar plate, a plate, a plate with non-uniform thickness and an object, and a method of use thereof.

### 2. Description of the Related Art

Mutual fixing and assembly is often needed in a non-planar plate, a plate, a plate with non-uniform thickness, an object or an electronic device.

However, a conventional means for fixing a heat sink is quite labor consuming, and tools such as screwdrivers are often needed for prying the heat sink open in a removal process, additionally rendering the removal process labor and time consuming.

### BRIEF SUMMARY OF THE INVENTION

With extensive research and development, the applicant provides a fixing structure and a method of use thereof with the aim of achieving the object of quickly assembling a non-planar plate, a plate, a plate with non-uniform thickness and an object in a labor-saving manner.

A fixing structure applied to arrange a heat dissipating device to a heat generating body on an object is provided according to a first aspect of the present disclosure. The fixing structure includes an entrance portion provided in the heat dissipating device and an elastic fastener provided on the object. The elastic fastener is arranged on the object, and includes a coupling head, a rod connected to the coupling head, and an elastic element sleeving the rod. The entrance portion is in communication with a slide portion, and the elastic fastener is adapted to enter the slide portion by the rod via the entrance portion and lean the coupling head against the heat dissipating device. The elastic element is for providing an elastic force for tightly securing the coupling head at the heat dissipating device, so as to press the heat dissipating device against the heat generating body to dissipate heat.

A fixing structure applied to arrange a heat dissipating device to a heat generating body on an object is provided according to a second aspect of the present disclosure. The fixing structure includes an entrance portion provided in the heat dissipating device and an elastic fastener provided on the object. The elastic fastener includes a coupling head, a rod connected to the coupling head, a body provided at the rod and arranged at the object, and an elastic element sleeving the rod. The entrance portion is in communication with a slide portion, or the entrance portion has a wide opening portion and is communication with the slide portion via the wide opening portion, and the elastic fastener is adapted to enter the slide portion by the rod via the entrance portion and lean the coupling head against the heat dissipating device, or the elastic fastener is adapted to enter the wide opening portion by the coupling head and then have the rod enter the slide portion, so that the coupling head leans against the heat dissipating device. The elastic element is for providing an elastic force for tightly securing the coupling head at the heat dissipating device, so as to press the heat dissipating device against the heat generating body to dissipate heat.

A fixing structure applied to arrange a heat dissipating device to a heat generating body on an object is provided according to a third aspect of the present disclosure. The fixing structure includes an entrance portion provided at the object and an elastic fastener arranged at the heat dissipating device. The entrance portion is in communication with a slide portion, and the elastic fastener is adapted to enter the slide portion by the rod via the entrance portion and lean the coupling head against the object. The elastic element is for providing an elastic force for tightly securing the coupling head at the object, so as to press the heat dissipating device against the heat generating body to dissipate heat.

A fixing structure applied to arrange a heat dissipating device to a heat generating body on an object is provided according to a fourth aspect of the present disclosure. The fixing structure includes an entrance portion provided at the object and an elastic fastener provided at the heat dissipating device. The elastic fastener includes a coupling head, a rod connected to the coupling head, and an elastic element sleeving the rod. The entrance portion is in communication with a slide portion, or the entrance portion has a wide opening portion and is communication with the slide portion via the wide opening portion, and the elastic fastener is adapted to enter the slide portion by the rod via the entrance portion and lean the coupling head against the object, or the elastic fastener is adapted to enter the wide opening portion by the coupling head and then have the rod enter the slide portion, so that the coupling head leans against the object. The elastic element is for providing an elastic force for tightly securing the coupling head at the object, so as to press the heat dissipating device against the heat generating body to dissipate heat.

A method of use of a fixing structure is provided according to a fifth aspect of the present disclosure to arrange a heat dissipating device on a heat generating body on an object by a fixing structure. The fixing structure includes an entrance portion provided at the heat dissipating device and an elastic fastener arranged at the object. The elastic fastener includes a coupling head, a rod connected to the coupling head, and an elastic element sleeving the rod. The entrance portion is in communication with a slide portion, or the entrance portion has a wide opening portion and is communication with the slide portion via the wide opening portion, and the elastic fastener enters the slide portion by the rod via the entrance portion and leans the coupling head against the heat dissipating device, or the elastic fastener enters the wide opening portion by the coupling head and then has the rod enter the slide portion, so that the coupling head leans against the heat dissipating device, and the elastic element provides an elastic force for tightly securing the coupling head at the heat dissipating device to press the heat dissipating device against the heat generating body to dissipate heat.

A method of use of a fixing structure is provided according to a sixth aspect of the present disclosure to arrange a heat dissipating device on a heat generating body on an object by a fixing structure. The fixing structure includes an entrance portion provided at the heat dissipating device and an elastic fastener arranged at the object. The elastic fastener includes a coupling head, a rod connected to the coupling head, a body provided at the rod and arranged at the object, and an elastic element sleeving the rod. The entrance portion is in communication with a slide portion, or the entrance portion has a wide opening portion and is communication with the slide portion via the wide opening portion, and the elastic fastener enters the slide portion by the rod via the entrance portion and leans the coupling head against the heat dissipating device, or the elastic fastener enters the wide opening portion by the coupling head and then has the rod enter the slide portion, so that the coupling head leans against the heat dissipating device, and the elastic element provides an elastic force for tightly securing the coupling head at the heat dissipating device to press the heat dissipating device against the heat generating body to dissipate heat.

A method of use of a fixing structure is provided according to a seventh aspect of the present disclosure to arrange a heat dissipating device on a heat generating body on an object by a fixing structure. The fixing structure includes an entrance portion provided at the object and an elastic fastener arranged at the heat dissipating device. The elastic fastener includes a coupling head, a rod connected to the coupling head, and an elastic element sleeving the rod. The entrance portion is in communication with a slide portion, or the entrance portion has a wide opening portion and is communication with the slide portion via the wide opening portion, and the elastic fastener enters the slide portion by the rod via the entrance portion and leans the coupling head against the object, or the elastic fastener enters the wide opening portion by the coupling head and then has the rod enter the slide portion, so that the coupling head leans against the object, and the elastic element provides an elastic force for tightly securing the coupling head at the object to press the heat dissipating device against the heat generating body to dissipate heat.

A method of use of a fixing structure is provided according to an eighth aspect of the present disclosure to arrange a heat dissipating device on a heat generating body on an object by a fixing structure. The fixing structure includes an entrance portion provided at the object and an elastic fastener arranged at the heat dissipating device. The elastic fastener includes a coupling head, a rod connected to the coupling head, a body connected to the rod and arranged at the object, and an elastic element sleeving the rod. The entrance portion is in communication with a slide portion, or the entrance portion has a wide opening portion and is communication with the slide portion via the wide opening portion, and the elastic fastener enters the slide portion by the rod via the entrance portion and leans the coupling head against the object, or the elastic fastener enters the wide opening portion by the coupling head and then has the rod enter the slide portion, so that the coupling head leans against the object, and the elastic element provides an elastic force for tightly securing the coupling head at the object to press the heat dissipating device against the heat generating body to dissipate heat.

A fixing structure applied to plug a printed circuit board having a connector into respective another connectors of an object and another object is provided according to a ninth aspect of the present disclosure. The fixing structure is for engaging the another object to the object, and includes an entrance portion provided at the another object and an elastic fastener provided at the object. The elastic fastener includes a coupling head, a rod connected to the coupling head, and an elastic element sleeving the rod. The entrance portion is in communication with a slide portion, and the elastic fastener is adapted to enter the slide portion by the rod via the entrance portion and lean the coupling head against the another object. The elastic element is for providing an elastic force for tightly securing the coupling head at the another object, so as to engage the another object with the object, and to engage the printed circuit board having the connector with the another object and connect to the respective another connectors of the object and the another object.

A fixing structure applied to plug a printed circuit board having a connector into respective another connectors of an object and another object is provided according to a tenth aspect of the present disclosure. The fixing structure is for engaging the another object with the object, and includes an entrance portion provided at the another object and an elastic fastener provided at the object. The elastic fastener includes a coupling head, a rod connected to the coupling head, and an elastic element sleeving the rod. The entrance portion is in communication with a slide portion, or the entrance portion has a wide opening portion and is communication with the slide portion via the wide opening portion, and the elastic fastener is adapted to enter the slide portion by the rod via the entrance portion and lean the coupling head against the printed circuit board, or the elastic fastener is adapted to enter the wide opening portion by the coupling head and then have the rod enter the slide portion, so that the coupling head leans against the another object. The elastic element is for providing an elastic force for tightly securing the coupling head at the another object, so as to engage the another object with the object, and to engage the printed circuit board having the connector with the another object and connect to the respective another connectors of the object and the another object.

A fixing structure applied to plug a printed circuit board having a connector into respective another connectors of an object and another object is provided according to an eleventh aspect of the present disclosure. The fixing structure is for engaging the another object with the object, and includes an entrance portion provided at the another object and an elastic fastener provided at the object. The elastic fastener is arranged on the object, and includes a coupling head, a rod connected to the coupling head, a body assembled at the rod and arranged at the object, and an elastic element sleeving the rod. The entrance portion is in communication with a slide portion, or the entrance portion has a wide opening portion and is communication with the slide portion via the wide opening portion, and the elastic fastener is adapted to enter the slide portion by the rod via the entrance portion and lean the coupling head against the another object, or the elastic fastener is adapted to enter the wide opening portion by the coupling head and then have the rod enter the slide portion, so that the coupling head leans against the another object. The elastic element is for providing an elastic force for tightly securing the coupling head at the another object, so as to engage the another object with the object, and to engage the printed circuit board having the connector with the another object and connect to the respective another connectors of the object and the another object.

A fixing structure is provided according to a twelfth aspect of the present disclosure. The fixing structure includes a heat dissipating device, an object and an elastic fastener. The heat dissipating device is provided with at least one non-planar plate, a plate or a plate with non-uniform thickness. The non-planar plate, the plate or the plate with non-uniform thickness is provided with at least one entrance portion and a slide portion in communication with the entrance portion. The object corresponds to the heat dissipating device. The elastic fastener is arranged at the object, and includes a coupling head, a rod connected to the coupling head, a body provided at the rod and arranged at the object, and an elastic element sleeving the rod. The elastic fastener is adapted to enter the slide portion by the coupling head via the entrance portion and lean the coupling head against the heat dissipating device, and provide an elastic force for tightly securing the coupling head against the heat dissipating device by the elastic element to press the heat dissipating device against a heat generating body to dissipate heat.

A fixing structure is provided according to a thirteenth aspect of the present disclosure. The fixing structure includes a heat dissipating device, an object and an elastic fastener. The heat dissipating device is provided with at least one non-planar plate, a plate or a plate with non-uniform thickness. The object corresponds to the heat dissipating device, and is provided with at least one engaged portion. The elastic fastener is arranged at the non-planar plate, the plate or the plate with non-uniform thickness and is engaged with the engaged portion. The elastic fastener includes an operating head, a rod connected to the operating head, a body provided at the rod and arranged at the non-planar plate, the plate or the plate with non-uniform thickness, an elastic element sleeving the rod, and an engaging portion provided at the rod. The operating head is rotated to engage the engaging portion with the engaged portion or to disengage the engaging portion from the engaged portion, and provide an elastic force by the elastic element to press the heat dissipating device against the heat generating body to dissipate heat.

A method of use of a fixing structure is provided according to a fourteenth aspect of the present disclosure. The fixing structure includes a heat dissipating device, an object and an elastic fastener. The heat dissipating device is provided with at least one non-planar plate, a plate or a plate with non-uniform thickness. The non-planar plate, the plate or the plate with non-uniform thickness is provided with at least one entrance portion and a slide portion in communication with the entrance portion. The object corresponds to the heat dissipating device. The elastic fastener is arranged at the object, and includes a coupling head, a rod connected to the coupling head, a body provided at the rod and arranged at the object, and an elastic element sleeving the rod. The elastic fastener is adapted to enter the slide portion by the coupling head via the entrance portion and lean the coupling head against the heat dissipating device, and provide an elastic force for tightly securing the coupling head against the heat dissipating device by the elastic element to press the heat dissipating device against a heat generating body to dissipate heat.

A method of use of a fixing structure is provided according to a fifteenth aspect of the present disclosure. The fixing structure includes a heat dissipating device, an object and an elastic fastener. The heat dissipating device is provided with at least one non-planar plate, a plate or a plate with non-uniform thickness. The object corresponds to the heat dissipating device, and is provided with at least one engaged portion. The elastic fastener is arranged at the non-planar plate, the plate or the plate with non-uniform thickness and is engaged with the engaged portion. The elastic fastener includes an operating head, a rod connected to the operating head, a body provided at the rod and arranged at the non-planar plate, the plate or the plate with non-uniform thickness, an elastic element sleeving the rod, and an engaging portion provided at the rod. The operating head is rotated to engage the engaging portion with the engaged portion or to disengage the engaging portion from the engaged portion, and provide an elastic force by the elastic element to press the heat dissipating device against the heat generating body to dissipate heat.

A fixing structure is provided according to a sixteenth aspect of the present disclosure. The fixing structure includes at least one non-planar plate, a plate or a plate with non-uniform thickness, an object and an elastic fastener. The non-planar plate, the plate or the plate with non-uniform thickness is provided with at least one entrance portion, or a slide portion in communication with the entrance portion. The object corresponds to the non-planar plate, the plate or the plate with non-uniform thickness. The elastic fastener is arranged at the object, and includes a coupling heat, or a rod connected to the coupling head, or a body provided at the rod and arranged at the object, or an elastic element sleeving the rod, or an elastic element provided at the elastic fastener; or the elastic fastener is adapted to enter the slide portion by the coupling head via the entrance portion, or lean the coupling head against the non-planar plate, the plate or the plate with non-uniform thickness, or provide an elastic force for tightly securing the coupling head against the non-planar plate, the plate or the plate with non-uniform thickness by the elastic element, or provide an elastic space by the coupling head.

A fixing structure is provided according to a seventeenth aspect of the present disclosure. The fixing structure includes at least one non-planar plate, a plate or a plate with non-uniform thickness, an object and an elastic fastener. The object corresponds to the non-planar plate, the plate or the plate with non-uniform thickness, and is provided with at least one engaged portion. The elastic fastener is arranged at the non-planar plate, the plate or the plate with non-uniform thickness, and is engaged with the engaged portion. The elastic fastener includes an operating head, or a rod connected to the operating head, a body provided at the rod and arranged at the non-planar plate, the plate or the plate with non-uniform thickness, or an elastic element sleeving the rod, or an elastic element provided at the elastic fastener, and an engaging portion provided at the rod; or the operating head is rotated to engage the engaging portion with the engaged portion or to disengage the engaging portion from the engaged portion, or provide an elastic extension and retraction space, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

A method of use of a fixing structure is provided according to an eighteenth aspect of the present. The elastic fastener is adapted to enter the slide portion by the coupling head via the entrance portion, or lean the coupling head against the heat dissipating device, or provide an elastic force for tightly securing the coupling head against the non-planar plate, the plate or the plate with non-uniform thickness by the elastic element, or provide an elastic space by the coupling head.

A method of use of a fixing structure is provided according to a nineteenth aspect of the present disclosure. The operating head is rotated to engage the engaging portion with the engaged portion or to disengage the engaging portion from the engaged portion, or provide an elastic extension and retraction space.

A method of use of a fixing structure is provided according to a twenty-first aspect of the present disclosure. The fixing structure is provided with an elastic fastener. The elastic fastener is adapted to enter a slide portion by a coupling head via an entrance portion, and is adapted to enter by a coupling head via an entrance portion, or lean the coupling head against a non-planar plate, a plate, a plate with non-uniform thickness or an object, or provide an elastic force for tightly securing the coupling head at the non-planar plate, the plate, the plate with non-uniform thickness or the object by an elastic element, or provide an elastic space by the coupling head, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

A method of use of a fixing structure is provided according to a twenty-second aspect of the present disclosure. The fixing structure is provided with an elastic fastener. The elastic fastener has an operating head, wherein the operating head is rotated to engage an engaging portion with an engaged portion of a non-planar plate, a plate, a plate with non-uniform thickness or an object, or to disengage the engaging portion from the engaged portion, or provide an elastic extension and retraction space by the elastic fastener, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

A method of use of a fixing structure is provided according to a twenty-third aspect of the present disclosure. The fixing structure is provided with an elastic fastener. The elastic fastener has an operating head or an engaging head to engage with a non-planar plate, a plate, a plate with non-uniform thickness or an object, or install at a non-planar plate, a plate, a plate with non-uniform thickness or an object so as to engage with the plate or the object. The non-planar plate, the plate or the plate with non-uniform thickness is heated at a high temperature and deforms into a non-planar plate or a plate with non-uniform thickness, or the non-planar plate, the plate or the plate with non-uniform thickness is heated at a high temperature and cooled and deforms into a non-planar plate or a plate with non-uniform thickness, or the non-planar plate, the plate or the plate with non-uniform thickness is heated at a high temperature and cooled and deforms into a non-planar printed circuit board or a plate with non-uniform thickness, or the non-planar plate, the plate or the plate with non-uniform thickness is heated at a high temperature and deforms into a non-planar printed circuit board or a plate with non-uniform thickness.

A fixing structure is provided according to a twenty-fourth aspect of the present disclosure. The fixing structure is provided with an elastic fastener. The elastic fastener is adapted to enter a slide portion by a coupling head via an entrance portion, or the elastic fastener is adapted to enter by a coupling head via an entrance portion, or lean the coupling head against a non-planar plate, a plate, a plate with non-uniform thickness or an object, or provide an elastic force for tightly securing the coupling head at the non-planar plate, the plate, the plate with non-uniform thickness or the object by an elastic element, or provide an elastic space by the coupling head, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

A fixing structure is provided according to a twenty-fifth aspect of the present disclosure. The fixing structure is provided with an elastic fastener, or the elastic fastener is provided with an operating head, or wherein the operating head is rotated to engage an engaging portion with an engaged portion of a non-planar plate, a plate, a plate with non-uniform thickness or an object, or to disengage the engaging portion from the engaged portion, or the elastic fastener is adapted to enter a non-planar plate, a plate or a plate with non-uniform thickness via an entrance portion, or the elastic fastener is adapted to enter a non-planar plate, a plate or a plate with non-uniform thickness via an entrance portion or a slide portion, or provide an elastic extension and retraction space by the elastic fastener.

A fixing structure is provided according to a twenty-sixth aspect of the present disclosure. The fixing structure includes at least one non-planar plate, a plate or a plate with non-uniform thickness, an object and an elastic fastener. The non-planar plate, the plate or the plate with non-uniform thickness is provided with at least one entrance portion, or a slide portion in communication with the entrance portion. The object corresponds to the non-planar plate, the plate or the plate with non-uniform thickness. The elastic fastener is arranged at the object, and includes a coupling head, or a rod connected to the coupling head, or a body provided at the rod and arranged at the object, or an elastic element sleeving the rod, or an elastic element provided at the elastic fastener; or the elastic fastener is adapted to enter the slide portion by the coupling head via the entrance portion; or the elastic fastener is adapted to enter by the coupling head via the entrance portion, or lean the coupling head against the non-planar plate, a plate or a plate with non-uniform thickness, or provide an elastic force for tightly securing the coupling head at the non-planar plate, a plate or a plate with non-uniform thickness by the elastic element, or provide an elastic space by the coupling head, or pull close a distance between an operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

A fixing structure is provided according to a twenty-seventh aspect of the present disclosure. The fixing structure includes at least one non-planar plate, a plate or a plate with non-uniform thickness; an object, corresponding to the non-planar plate, the plate or the plate with non-uniform thickness; and an elastic fastener, arranged at the object, the elastic fastener including a coupling head, or a rod connected to the coupling head, or a body provided at the rod and arranged at the object, or an elastic element sleeving the rod, or an elastic element provided at the elastic fastener, or for leaning the coupling head against the non-planar plate, a plate or a plate with non-uniform thickness, or for providing an elastic force for engaging the coupling head with the non-planar plate, a plate or a plate with non-uniform thickness by the elastic element, or for providing an elastic space by the coupling head, or for pulling close a distance between the operating head and an engaged portion of a non-planar plate, a plate, a plate with non-uniform thickness or an object, or for elastically compressing, elastically pressing or elastically separating a distance, an elastic distance or an elastic interval between the operating head and an engaged portion of a non-planar plate, a plate, a plate with non-uniform thickness or an object.

A fixing structure is provided according to a twenty-eighth aspect of the present disclosure. The fixing structure is provided with an elastic fastener. The elastic fastener is adapted to lean against a non-planar plate, a plate, a plate with non-uniform thickness or an object by a coupling head, or provide an elastic force for tightly securing the coupling head at the non-planar plate, the plate, the plate with non-uniform thickness or the object by an elastic element, or provide an elastic space by the coupling head, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

A method of use of a fixing structure is provided according to a twenty-ninth aspect of the present disclosure. The fixing structure is provided with an elastic fastener. The elastic fastener is adapted to lean against a non-planar plate, a plate, a plate with non-uniform thickness or an object by a coupling head, or provide an elastic force for tightly securing the coupling head at the non-planar plate, the plate, the plate with non-uniform thickness or the object by an elastic element, or provide an elastic space by the coupling head, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

A method of use of a fixing structure is provided according to a thirtieth aspect of the present disclosure. The fixing structure is provided with an elastic fastener. The elastic fastener has an operating head or a coupling head to engage with a non-planar plate, a plate, a plate with non-uniform thickness or an object; or install at a non-planar plate, a plate, a plate with non-uniform thickness or an object so as to engage with a plate or an object, or wherein the non-planar plate, the plate or the plate with non-uniform thickness is heated at a high temperature and deforms into a non-planar plate or a plate with non-uniform thickness, or the non-planar plate, the plate or the plate with non-uniform thickness is heated at a high temperature and cooled and deforms into a non-planar plate or a plate with non-uniform thickness, or the non-planar plate, the plate or the plate with non-uniform thickness is heated at a high temperature and cooled and deforms into a non-planar printed circuit board or a printed circuit board with non-uniform thickness, or the non-planar plate, the plate or the plate with non-uniform thickness is heated at a high temperature and deforms into a non-planar printed circuit board or a printed circuit board with non-uniform thickness; or pull close a distance between the coupling head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

In one embodiment above, the object, the non-planar plate, the plate or the plate with non-uniform thickness is a printed circuit board, a metal plate, a heat dissipating device, a heat dissipating body, an electronic element, a metal body, a plastic body, a non-metal body, a casing, an electronic device, an integrated circuit, a plastic plate or a non-metal plate.

In one embodiment above, the elastic fastener is provided with a stopping portion, which is for defining an elastic space for the elastic fastener to use the elastic space to adjust an engaging height.

In one embodiment above, the elastic fastener is adapted to laterally or vertically fit into the entrance portion.

In one embodiment above, the coupling head has a guide surface, which is for guiding the coupling head to move upward onto the slide portion when the rod enters the entrance portion or the slide portion.

In one embodiment above, the non-planar plate, the plate or the plate with non-uniform thickness is provided at a heat dissipating device.

In one embodiment above, a printed circuit board having a connector is plugged into another connector of the object, the non-planar plate, the plate, the plate with non-uniform thickness or another object, or the elastic fastener is for engaging the non-planar plate, the plate, the plate with non-uniform thickness or the another object with the object.

In one embodiment above, the elastic fastener is a coupling head, a thread, a column, an outer fastener, an inner fastener or an elastic fastener.

In one embodiment above, the elastic fastener is engagement connected, rivet connected, expansion connected, weld connected or lock connected to the non-planar plate, the plate, the plate with non-uniform thickness or the object, or the elastic fastener and the non-planar plate, the plate, the plate with non-uniform thickness or the object are formed integrally.

In one embodiment above, the non-planar plate, the plate or the plate with non-uniform thickness is heated at a high temperature and deforms into a non-planar plate, or the non-planar plate, the plate or the plate with non-uniform thickness is heated at a high temperature and cooled and deforms into a non-planar plate, or the non-planar plate, the plate or the plate with non-uniform thickness is heated at a high temperature and cooled and deforms into a non-planar printed circuit board, or the non-planar plate, the plate or the plate with non-uniform thickness is heated at a high temperature and deforms into a non-planar printed circuit board.

In one embodiment above, the non-planar plate, the plate, the plate with non-uniform thickness or the object is a printed circuit board for hot-plugging at a connector, or the non-planar plate is a printed circuit board, the plate, the plate with non-uniform thickness or the object for horizontally or vertically hot-plugging at a connector, or the non-planar plate is a printed circuit board, the plate, the plate with non-uniform thickness or the object for engaging and hot-plugging at a connector by the elastic fastener, or the non-planar plate is a printed circuit board, the plate, the plate or the plate with non-uniform thickness or the object for horizontally or vertically engaging and hot-plugging at a connector by the elastic fastener.

In one embodiment above, the object is a non-planar plate or a plate with non-uniform thickness for two non-planar plates or two plates with non-uniform thickness to be engaged with each other.

In one embodiment above, the non-planar plate, the plate, the plate with non-uniform thickness, the object or another object is assembled with two or more non-planar plates, or wherein the two or more non-planar plates, plates or plates are at top-down positions or horizontal positions.

In one embodiment above, the elastic fastener is provided with another elastic element. The another elastic element is for blocking against the non-planar plate, the plate, the plate with non-uniform thickness or the object, or the another elastic element is for blocking against or clamping at the non-planar plate, the plate, the plate with non-uniform thickness or the object by the coupling head, or the another elastic element is for blocking against the non-planar plate or the object by a blocking portion, or the another elastic element is for blocking against or clamping at the non-planar plate, the plate, the plate with non-uniform thickness or the object by a blocking portion and the coupling head.

In one embodiment above, the elastic fastener is provided with a blocking portion. The blocking portion is for generating a blocking space when the coupling head is engaged with the non-planar plate, the plate, the plate with non-uniform thickness or the object, or the blocking space is generated by the coupling head and the blocking portion pressing against the non-planar plate, the plate, the plate with non-uniform thickness or the object.

In one embodiment above, the coupling head is provided with at least one step portion. The step portion is for limiting, leaning against, clamping or pressing downward at the non-planar plate, the plate, the plate with non-uniform thickness or the object.

In one embodiment above, the rod and the body of the elastic fastener are movably combined, integrally formed, or fixedly combined.

Thus, the fixing structure and the method of use thereof of the present disclosure are capable of quickly removing or mounting a non-planar plate, a plate or a plate with non-uniform thickness at an object in an effort-saving manner.

### BRIEF DESCRIPTION OF THE DRAWINGS

FIG. 1 is a first perspective schematic diagram of a fixing structure according to a specific embodiment of the present disclosure.

FIG. 2 is a cross-sectional schematic diagram of the fixing structure in FIG. 1.

FIG. 3 is a second perspective schematic diagram of a fixing structure according to a specific embodiment of the present disclosure.

FIG. 4 is a cross-sectional schematic diagram of the heat dissipating device in FIG. 3.

FIG. 5 is a schematic diagram of operation of the elastic fastener corresponding to FIG. 1 engaging a heat dissipating device.

FIG. 6 is a schematic diagram of engaging of another fastener according to a specific embodiment of the present disclosure.

FIG. 7 is a first schematic diagram of engaging of an elastic fastener and a heat dissipating device according to a specific embodiment of the present disclosure.

FIG. 8 is a second schematic diagram of engaging of an elastic fastener and a heat dissipating device according to a specific embodiment of the present disclosure.

FIG. 9 is a schematic diagram of an assembly method of a fixing structure according to a specific embodiment of the present disclosure.

FIG. 10 is a top schematic diagram of a body in different shapes of an elastic fastener according to a specific embodiment of the present disclosure.

FIG. 11 is a flowchart of assembling an object, another object and a printed circuit board according to a specific embodiment of the present disclosure.

FIG. 12 is a schematic diagram of a second specific embodiment of the present disclosure.

FIG. 13 is a schematic diagram of a third specific embodiment of the present disclosure.

FIG. 14 is a schematic diagram of a fourth specific embodiment of the present disclosure.

FIG. 15 is a schematic diagram of a fifth specific embodiment of the present disclosure.

FIG. 16 is a schematic diagram of a sixth specific embodiment of the present disclosure.

FIG. 17 is a schematic diagram of a seventh specific embodiment of the present disclosure.

FIG. 18 is a schematic diagram of different forms of an elastic fastener of the present disclosure.

FIG. 19 is a schematic diagram of an eighth specific embodiment of the present disclosure.

FIG. 20 is a schematic diagram of a ninth specific embodiment of the present disclosure.

FIG. 21 is a schematic diagram of different forms of an engaging portion of the present disclosure.

FIG. 22 is a schematic diagram of a tenth specific embodiment of the present disclosure.

FIG. 23 is a schematic diagram of an eleventh specific embodiment of the present disclosure.

FIG. 24 is a schematic diagram of a twelfth specific embodiment of the present disclosure.

FIG. 25 is a schematic diagram of a thirteenth specific embodiment of the present disclosure.

FIG. 26 is a schematic diagram of a fourteenth specific embodiment of the present disclosure.

### DETAILED DESCRIPTION OF THE INVENTION

To facilitate understanding of the objective, characteristics and effects of the present disclosure, embodiments together with the attached drawings for the detailed description of the present disclosure are provided below.

Aspects of the present disclosure are provided below.

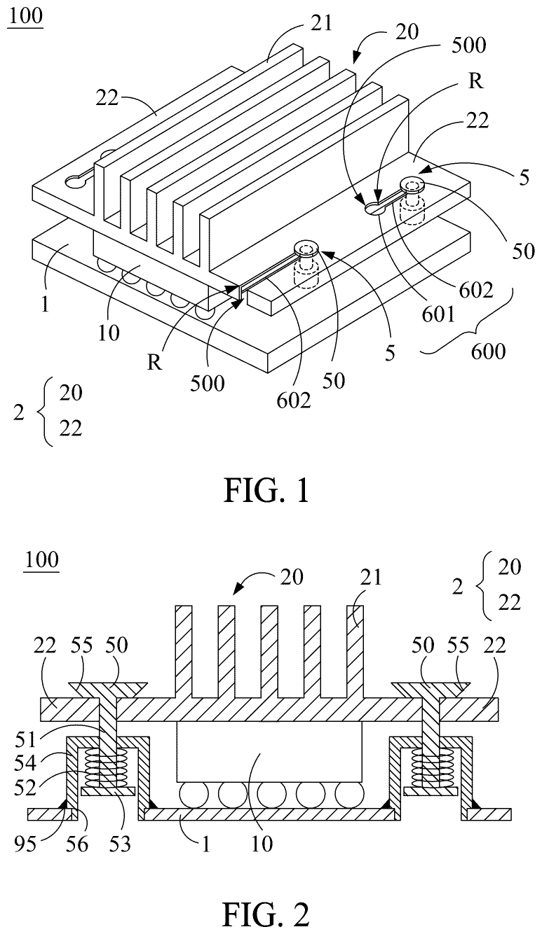

Referring to FIG. 1 and FIG. 2, a fixing structure 100 applied to arrange a heat dissipating device 2 to a heat generating body 10 on an object 1 is provided according to a first embodiment of the present disclosure. The fixing structure 100 includes an entrance portion 500 provided on the heat dissipating device 2, and an elastic fastener 5 provided on the object 1. The elastic fastener 5 is arranged on the object 1, and includes a coupling head 50, a rod 51 connected to the coupling head 50, and an elastic element 52 sleeving the rod 51. The entrance portion 500 is in communication with a slide portion 602, and the elastic fastener 5 is adapted to enter the slide portion 602 by the rod 51 via the entrance portion 500 and lean the coupling head 50 against the heat dissipating device 2. The elastic element 52 is for providing an elastic force for tightly securing the coupling head 50 at the heat dissipating device 2, so as to press the heat dissipating device 2 against the heat generating body 10 to dissipate heat.

Referring to FIG. 1 and FIG. 2, a second aspect of the present disclosure is substantially the same as the first aspect, and differs in that the elastic fastener 5 further includes a body 54. The body 54 is provided at the rod 51 and is arranged at the object 1, and/or the entrance portion 500 may have a wide opening portion 601 by which the entrance portion 500 is in communication with the slide portion 602. The elastic fastener 5 is adapted to enter the wide opening portion 601 by the coupling head 50 and then have the rod 51 enter the slide portion 602, so that the coupling head 50 leans against the heat dissipating device 2.

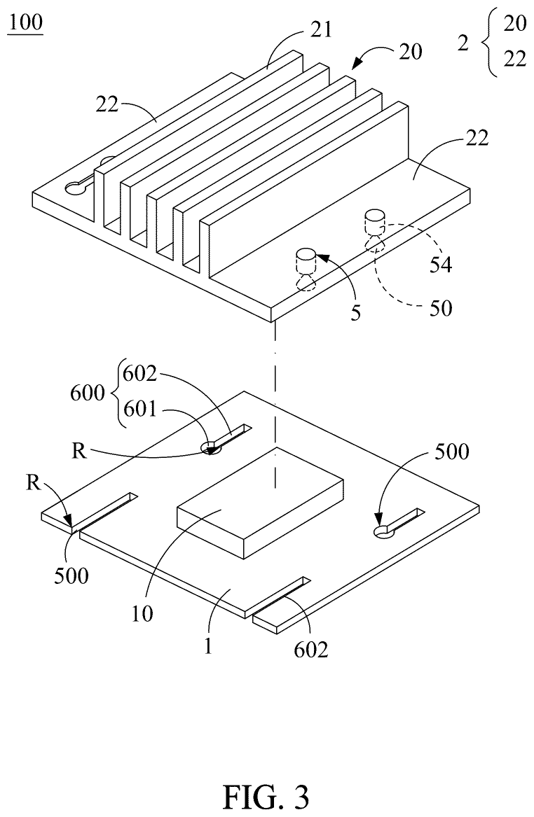

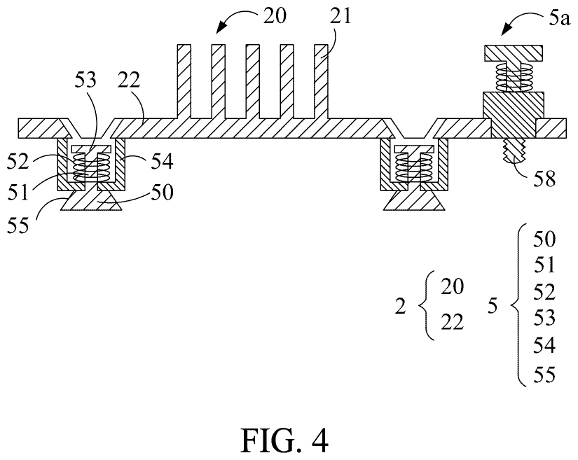

Referring to FIG. 3 and FIG. 4, a third aspect of the present disclosure is similar to the first aspect, and differs merely in that the entrance portion 500 is provided at the object 1 while the elastic fastener 5 is provided on the heat dissipating device 2.

Referring to FIG. 3 and FIG. 4, a fourth aspect of the present disclosure is similar to the second aspect, and differs merely in that the entrance portion 500 and the wide opening portion 601 are provided at the object 1 while the elastic fastener 5 is provided on the heat dissipating device 2.

Referring to FIG. 1 and FIG. 2, a method of use of a fixing structure is provided according to a fifth aspect of the present disclosure. The method of use of a fixing structure is to arrange the heat dissipating device on the heat generating body 10 on the object 1 by using the fixing structure 100 of the first aspect.

Referring to FIG. 1 and FIG. 2, a method of use of a fixing structure is provided according to a sixth aspect of the present disclosure. The method of use of a fixing structure is to arrange the heat dissipating device on the heat generating body 10 on the object 1 by using the fixing structure 100 of the second aspect.

Referring to FIG. 3 and FIG. 4, a method of use of a fixing structure is provided according to a seventh aspect of the present disclosure. The method of use of a fixing structure is to arrange the heat dissipating device 2 on the heat generating body 10 on the object 1 by using the fixing structure 100 of the third aspect.

Referring to FIG. 3 and FIG. 4, a method of use of a fixing structure is provided according to an eighth aspect of the present disclosure. The method of use of a fixing structure is to arrange the heat dissipating device 2 on the heat generating body 10 on the object 1 by using the fixing structure 100 of the fourth aspect.

Referring to FIG. 1, FIG. 2 and FIG. 11, a fixing structure 100 is provided according to a ninth aspect of the present disclosure. The fixing structure 100 is applied to plug a printed circuit board 23 having a connector 230 into respective another connectors 16 of the object 1 and another object 24. The fixing structure 100 is for engaging the another object 24 with the object 1, and includes an entrance portion 500 provided at the another object 24 and the same as that of the first aspect, and an elastic fastener 5 provided at the object 1 and the same as that of the first aspect. The elastic fastener 5 is provided at the object 1, and the entrance portion 500 and the slide portion 602 are provided at the another object 24. When the coupling head 50 of the elastic fastener 5 slides to a predetermined position in the slide portion 602, the another connector 16 of the object 1 is also plugged into the connector 230, and the another connector 16 of the another object 24 can be first plugged into the connector 230, or the orders of plugging can be swapped. In this aspect, the elastic element 52 is for providing an elastic force for tightly securing the coupling head 50 at the another object 24, so as to engage the another object 24 with the object 1, and engage the printed circuit board 23 having the connector 230 with the another object 24 and connect to the respective another connectors 16 of the object 1 and the another object 24. The connector 230 may be a plug having a golden finger, and the another connector 16 may be a corresponding receptacle, or the configurations of the two may be swapped. The printed circuit board 23 is adapted to be plugged with the connector 230 and the another connector 16; however, the present disclosure is not limited to the above examples.

Referring to FIG. 1, FIG. 2 and FIG. 11, a fixing structure 100 is provided according to a tenth aspect of the present disclosure. This aspect is similar to the ninth and the second aspects; the entrance portion 500 may have a wide opening portion 601 and is in communication with the slide portion 602 via the wide opening portion 601, and the elastic fastener 5 is adapted to enter the wide opening portion 601 (as shown in FIG. 2) by the coupling head 50 and then have the rod 51 enter the slide portion 602, so that the coupling head 50 leans against the another object 24.

Referring to FIG. 1, FIG. 2 and FIG. 11, a fixing structure 100 is provided according to an eleventh aspect of the present disclosure, and is similar to the tenth and the second aspects. The elastic fastener 5 further includes a body 54 provided at the object 1. The ninth to eleventh aspects can also be integrated into the first to fourth aspects. That is, the fixing structure 100 can be simultaneously used to press the heat dissipating device 2 on the heat generating body 10 and used for plugging and positioning among a plurality of printed circuit boards.

Referring to FIG. 1 and FIG. 2, in one embodiment, the heat generating body 10 may be an integrated circuit, a central processing unit (CPU), a graphics processing unit (GPU), a storage medium or a hard drive.

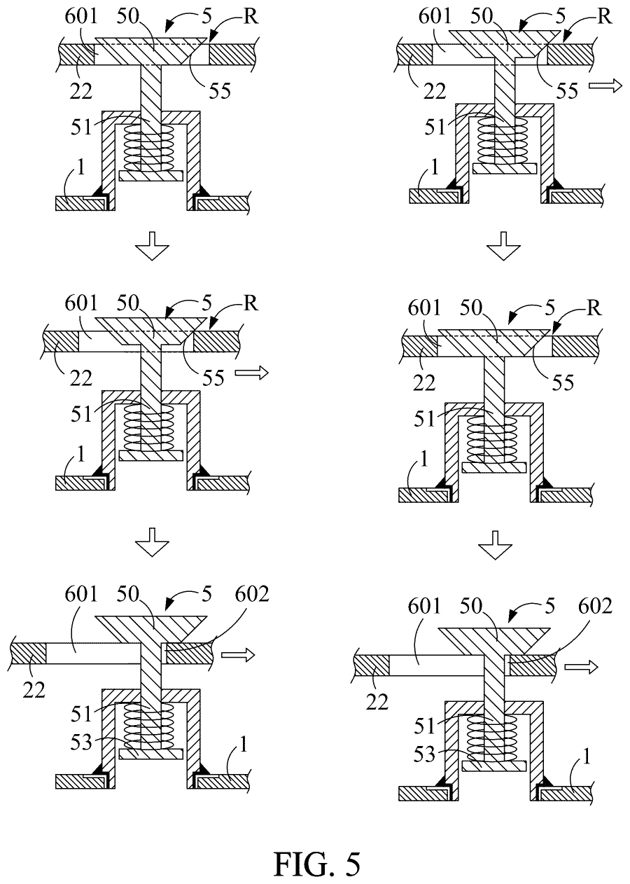

As shown in FIG. 1, FIG. 2 and FIG. 5, in one embodiment, the heat dissipating device 2 includes a heat sink body 20 having a plurality of cooling fins 21 and two flanks 22 respectively extending on two sides of the heat sink body 20. The wide opening portion 601 and the slide portion 602 in communication with each other may be integrated into a limiting portion 600. Each flank 22 is provided with the entrance portion 500 or the limiting portion 600. The entrance portion 500 may be an opening provided on one side of the flank 22 and extending inward to form a slide portion 602 in the form of an open groove, the rod 51 of the elastic fastener 5 may enter the opening of the entrance portion 500 along a lateral direction and be stopped at an end of the slide portion 602, and the elastic fastener 5 fastens the heat dissipating device 2 at the object 1 at the end. The limiting portion 600 is an opening provided at an interior of the flank 22. The limiting portion 600 has a larger aperture at the wide opening portion 601 to allow the coupling head 50 of the elastic fastener 5 to enter, and the slide portion 602 has a less width to limit up and down movements of the coupling head 50 and to allow the elastic fastener 5 to be fitted only along the lateral direction. The wide opening portion 601 of the limiting portion 600 may also be regarded as a form in which the entrance portion 500 is located in the flank 22. In FIG. 1, each of the flanks 22 of the heat dissipating device 2 is provided with both the entrance portion 500 and the limiting portion 600, and the object 1 is provided with the elastic fasteners 5 respectively corresponding to the entrance portion 500 and the limiting portion 600; however, the present disclosure is not limited to the examples above. Part of the rod 51 is inserted in the body 54, and the elastic fastener 5 may further include a stopping portion 53. The stopping portion 53 may be provided at the end of the rod 51 located in the body 54, and the elastic element 52 is, for example, a compression spring capable of abutting between the stopping portion 53 and the body 54.

As shown in FIG. 2, FIG. 4 and FIG. 11, in one embodiment, the coupling head 50 of the aspects above may use a spring force of the elastic element 52 to press against and clamp a corresponding object (or the object 1, the heat dissipating device 2 or the another object 24), wherein the spring force may be between 0.00001 kgf and 50 kgf.

As shown in FIG. 3 and FIG. 4, in one embodiment, the two flanks 22 of the heat dissipating device 2 may be used to arrange the elastic fasteners 5, for example, being connected to the bodies 54 of the elastic fasteners 5. Compared with FIG. 1 and FIG. 2, the entrance portion 500 and the limiting portion 600 are provided on the object 1 instead. In FIG. 3, the object 1 is provided with both the entrance portion 500 and the limiting portion 600, and each of the flanks 22 is provided with the elastic fasteners 5 respectively corresponding to the entrance portion 500 and the limiting portion 600; however, the present disclosure is not limited to the examples above.

As shown in FIG. 1 to FIG. 4 and FIG. 11, the object 1 or the another object 24 may be a printed circuit board (PCB), a metal plate, a heat dissipating device, a heat dissipating body, an electronic element, a metal body, a plastic body, a non-metal body, a casing, an electronic device, an integrated circuit, a plastic plate or a non-metal plate.

As shown in FIG. 1 to FIG. 5, in one embodiment, the coupling head 50 may have a guide surface 55. The guide surface 55 is for guiding the coupling head 50 to move onto the slide portion 602 when the rod 51 enters the slide portion 602. The entrance portion 500 or the slide portion 602 has a lift portion R, which is to lift the coupling head 50 when the coupling head 50 is used for engaging. The guide surface 55 or the lift portion R may be an inclined surface, a circular surface, a curved surface or a stepped surface. The lift portion R may be provided on an edge of the opening of the entrance portion 500, or at a boundary between the slide portion 602 and the wide opening portion 601.

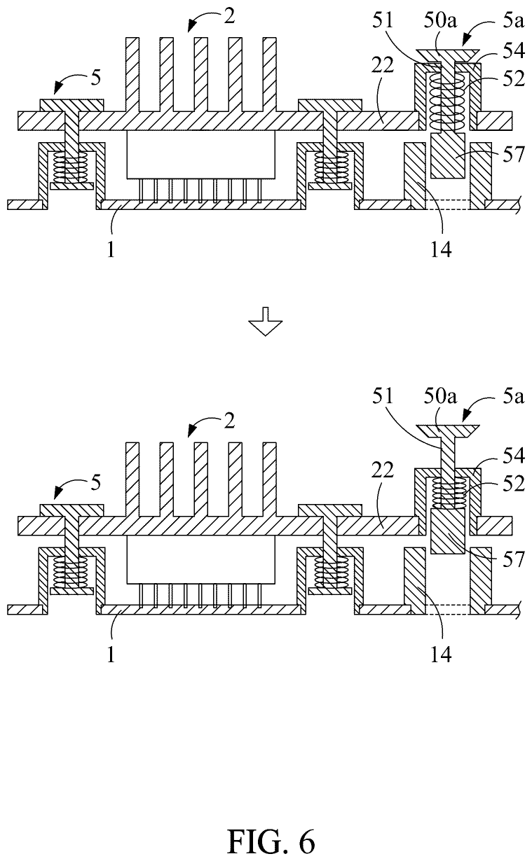

As shown in FIG. 6 and FIG. 4, the fixing structure 100 of the present disclosure may further include another fastener 5a. When the heat dissipating device 2 and the object 1 are mutually engaged to a predetermined position by the elastic fastener 5 (for example, when the elastic fastener 5 in FIG. 1 or FIG. 3 slides to the end of the entrance portion 500 or the slide portion 602), the heat dissipating device 2 is positioned by the another fastener 5a using the horizontal movement relative to the object 1. For example, the another fastener 5a may be provided at the object 1; once the heat dissipating device 2 and the object 1 are mutually engaged by the elastic fastener 5, the another fastener 5a is used to engaged the object 1 with the heat dissipating device 2. Alternatively, the another fastener 5a may also be provided at the heat dissipating device 2; once the heat dissipating device 2 and the object 1 are mutually engaged by the elastic fastener 5, the another fastener 5a is used to engage the heat dissipating device 2 with the object 1. In FIG. 6 and FIG. 4, the another fastener 5a is provided at the flank 22 of the heat dissipating device 2; however, the present disclosure is not limited to the example above. In FIG. 6, the another fastener 5a is in the form of an elastic fastener structure, and in FIG. 4, the another fastener 5a has a thread 58; however, the present disclosure is not limited to the examples above. The another fastener 5a may also be provided with a column, an outer fastener or an inner fastener. In FIG. 6, the another fastener 5a includes a body 54 connected to the heat dissipating device 2, a rod 51 sleeving the body 54, an engaging portion 57 provided at a bottom end of the rod 51, an operating head 50a connected to a top end of the rod 51, and an elastic element 52 abutting between the body 54 and the engaging portion 57. The object 1 has an engaged portion 14 in the form of a cylinder. The engaging portion 57 can be engaged with or disengaged from the engaged portion 14 by rotating the operating head 50a.

As shown in FIG. 2, in one embodiment, the body 54 is connected to the rod 51 and has a weldable surface 56. The weldable surface 56 may also be provided at the object 1, and a solder layer 95 may be provided on the weldable surface 56, so that welding can be performed by heating the weldable surface 56 and the solder layer 95.

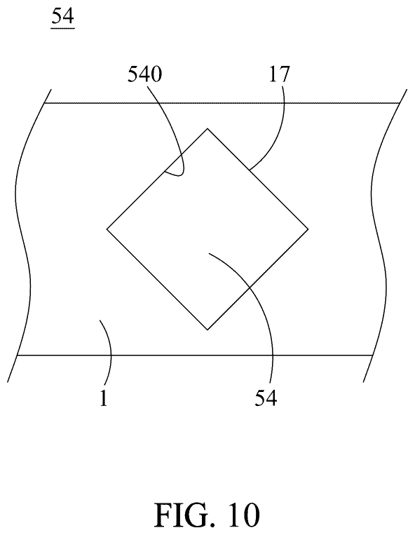

As shown in FIG. 10, the body 54 may have an anti-rotation portion 540. For example, the anti-rotation portion 540 may be in the form of a polygon of the body 54, so as to provide an anti-rotation effect when arranged at the object 1 or the heat dissipating device 2 of FIG. 1 to FIG. 4, and to facilitate an assembly process such as welding. For example, the body 1 may be provided with a corresponding anti-rotation portion 17. The corresponding anti-rotation portion 17 may be a slot or an opening corresponding in shape to the anti-rotation portion 540, so as to implement an anti-rotation function.

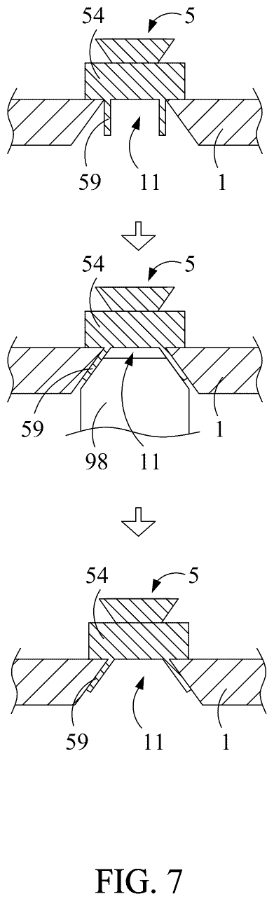

As shown in FIG. 7, in one embodiment, a bottom portion of the body 54 of the elastic fastener 5 may be provided with an expansion connecting portion 59, and the object 1 may be provided with an expansion connecting hole 11. With a tightening member 98, the expansion connecting portion 59 is pressed at the expansion connecting hole 11 to fit the body 54 into the object 1. The heat dissipating device 2 in FIG. 4 may also be assembled with the elastic fastener 5 by the same method.

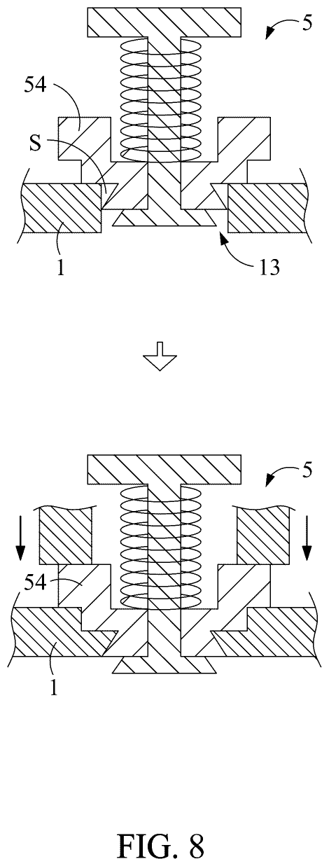

As shown in FIG. 8, in one embodiment, the body 54 of the elastic fastener 5 may have a material storage space S, and the object 1 may be provided with a feed hole 13. By pressing the body 54, a material of the object 1 is enabled to enter or flow into the material storage space S to rivet connect the body 54 at the object 1. The heat dissipating device 2 in FIG. 4 may also be assembled with the elastic fastener 5 by the same method. However, the present disclosure is not limited to the examples above. For example, the body 54 may also be provided with an assembly portion in other forms to lock connect or engagement connect the object 1.

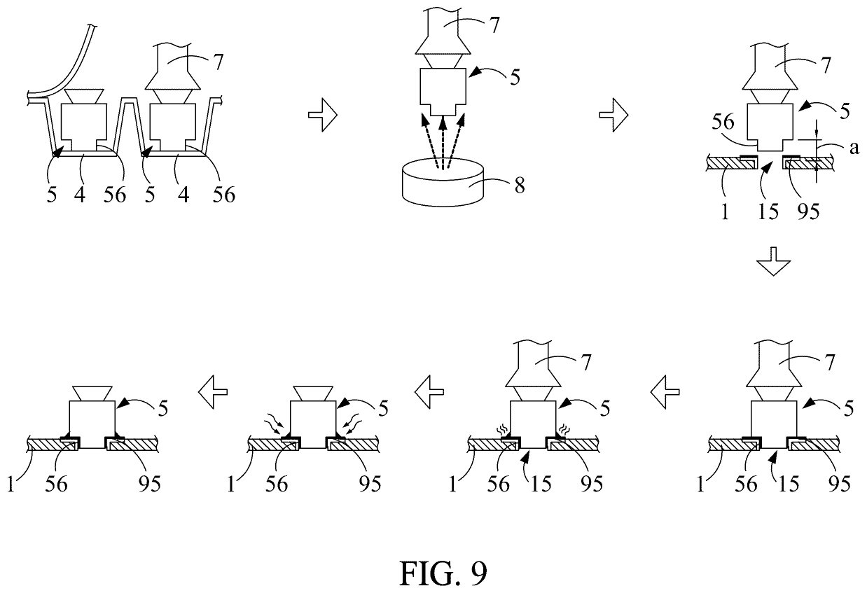

Refer to FIG. 9 as well as FIG. 1 to FIG. 4. In another aspect of the present disclosure, a method for assembling the fixing structure 100 to the heat dissipating device 2 or the object 1 is provided. FIG. 8 depicts a process for assembling the fixing structure 100 to the object 1 as an example for illustrations. Before being assembled to the object 1, the fixing structure 100 may be placed in a carrier 4. The fixing structure 100 has the weldable surface 56 used for arranging solder as described above, and the object 1 has a through hole 15. The method includes the steps of:
providing a tool 7 to pick up the fixing structure 100 from the carrier 4;
using the tool 7 to move the fixing structure 100 to a predetermined height a on an assembly position (that is, the through hole 15) of the object 1; and
releasing or setting free the fixing structure 100 from the tool 7, so that the fixing structure 100 drops and becomes placed at the assembly position of the object 1. Thus, the fixing structure 100 can be fixed at the object 1 to improve efficiency of subsequent processes. The tool 7 may be a clamp, a fixture, a vacuum suction device, a magnetic suction device or an elastic motion element in order to meet actual assembly requirements.

In one embodiment, after the fixing structure 100 is picked up by the tool 7 from the carrier 4, positions of or a distance between the fixing structure 100 and the assembly position of the object 1 can be compared by a comparison device 8, the tool 7, according to comparison information from the comparison device 8, moves the fixing structure 100 to the predetermined height a (which may be 0.000001 mm to 10 mm) on the object 1 and releases or sets free the fixing structure 100 to allow the fixing structure 100 drop to the assembly position of the object 1, and then the weldable surface 56 and the solder layer 95 may be heated and welded to weld the fixing structure 100 at the object 1. In one embodiment, the comparison device 8 may be a vision comparison device, a distance comparison device, an image comparison device, an AI comparison device or a camera comparison device in order to meet actual assembly requirements.

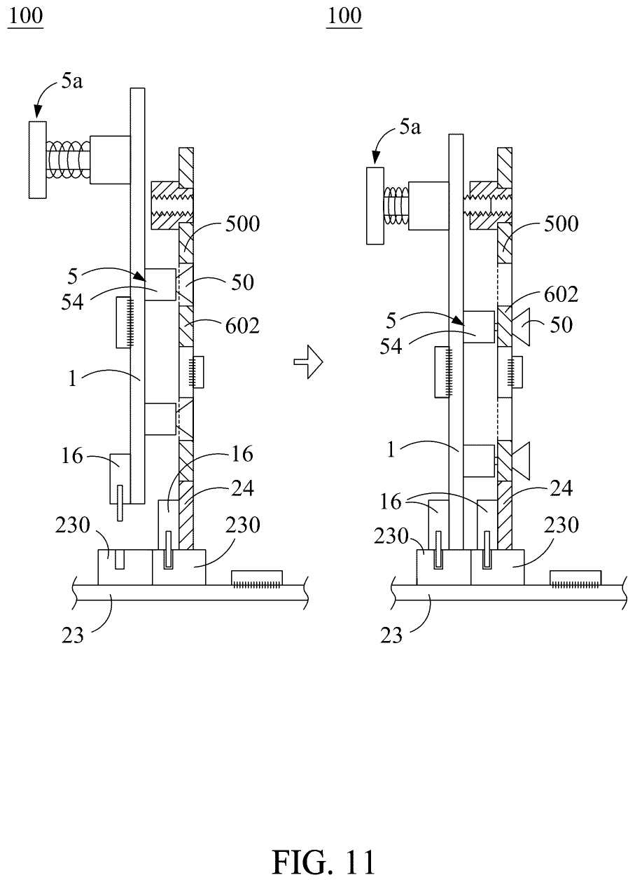

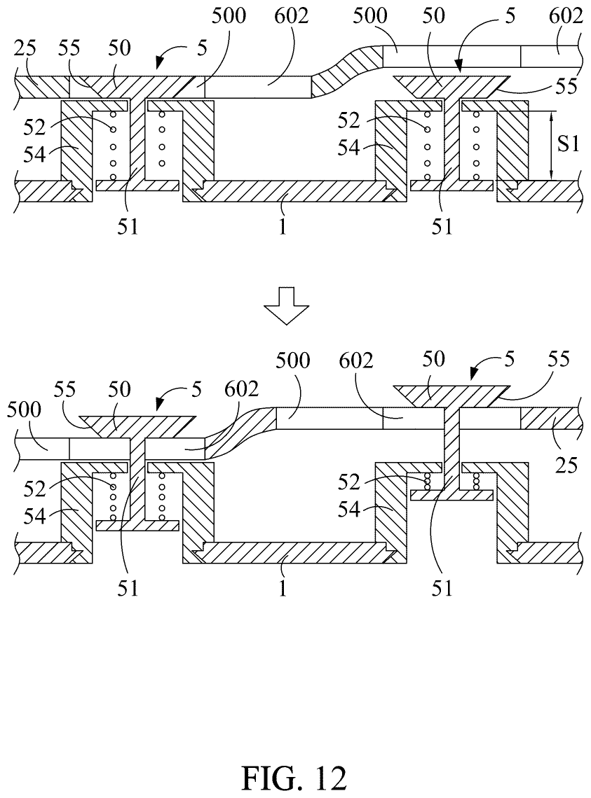

Referring to FIG. 12, another fixing structure 100 is provided according to an embodiment of the present disclosure. The fixing structure 100 includes at least one non-planar plate 25 (or a plate, or a plate with non-uniform thickness), an object 1 and an elastic fastener 5. In this embodiment, the non-planar plate 25 is provided at a heat dissipating device 2 (or a heat dissipating body, a printed circuit board, an electronic element, an integrated circuit, a metal body, a plastic body, a non-metal body, a casing or an electronic device).

The heat dissipating device 2 is provided with at least one non-planar plate 25 (which may be the flank 22 above). The non-planar plate 25 is provided with at least one entrance portion 500 and a slide portion 602 in communication with the entrance portion 500. The object 1 corresponds to the heat dissipating device 2. The elastic fastener 5 is arranged at the object 1, and includes a coupling head 50, a rod 51 connected to the coupling head 50, a body 54 provided at the rod 51 and arranged at the object 1, and an elastic element 52 sleeving the rod 51. The elastic fastener 5 is adapted to enter the slide portion 602 by the coupling head 50 via the entrance portion 500 and lean the coupling head 50 against the heat dissipating device 2, and provide an elastic force for tightly securing the coupling head 50 at the heat dissipating device 2 by the elastic element 52, so as to press the heat dissipating device 2 against the heat generating body 10 to dissipate heat.

In one embodiment, the elastic fastener 5 is adapted to laterally (or vertically) fit into the entrance portion 500, thereby enabling the present disclosure to better meet actual application requirements.

In one embodiment above, the coupling head 50 has a guide surface 55, which is for guiding the coupling head 50 to move upward onto the slide portion 602 when the rod 51 enters the entrance portion 500 or the slide portion 602, thereby enabling the present disclosure to better meet actual application requirements.

In one embodiment, the coupling head 50 provides an elastic space S1 for the elastic fastener 5 to use the elastic space S1 to adjust an engaging height and a pressing force for fastening of the coupling head 50, thereby enabling the present disclosure to better meet actual application requirements.

In one embodiment above, the object 1 or the non-planar plate 25 (or the plate, the plate with non-uniform thickness or the object 1) may be a printed circuit board, a metal plate, a heat dissipating device, a heat dissipating body, an electronic element, a metal body, a plastic body, a non-metal body, a casing, an electronic device, an integrated circuit, a plastic plate or a non-metal plate, thereby enabling the present disclosure to better meet actual application requirements.

In one embodiment above, the elastic fastener 5 is a coupling head, a thread, a column, an outer fastener, an inner fastener or an elastic fastener, thereby enabling the present disclosure to better meet actual application requirements.

In one embodiment, the elastic fastener 5 is engagement connected, rivet connected, expansion connected, weld connected or lock connected to the non-planar plate 25 or the object 1, or the elastic fastener 5 and the non-planar plate 25 or the object 1 are formed integrally, thereby enabling the present disclosure to better meet actual application requirements.

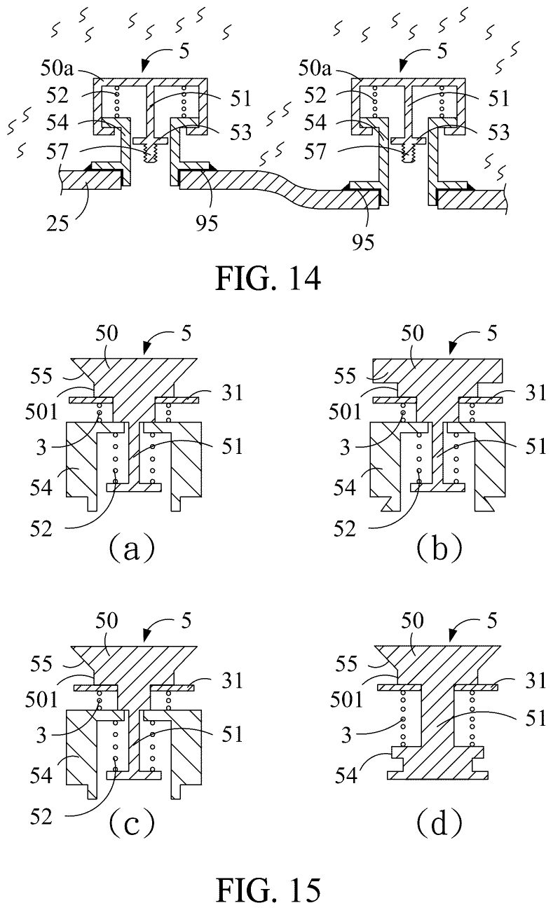

In one embodiment above, the non-planar plate 25 (or the plate, the plate with non-uniform thickness or the object 1) may be heated at a high temperature and deform into a non-planar plate or a plate with non-uniform thickness, or the non-planar plate 25 may be heated at a high temperature and cooled and deform into a non-planar plate or a plate with non-uniform thickness, or the non-planar plate 25 may be heated at a high temperature and cooled and deform into a non-planar printed circuit board or a printed circuit board with non-uniform thickness (as shown in FIG. 14), or the non-planar plate 25 may be heated at a high temperature and deform into a non-planar printed circuit board or a printed circuit board with non-uniform thickness (as shown in FIG. 14), thereby enabling the present disclosure to better meet actual application requirements.

In one embodiment, the non-planar plate 25 may also be provided with a connector 230 or another connector 16 as shown in FIG. 11, so as to plug with the another connector 16 of the object 1 or the another object 24 or the connector 230. For example, the non-planar plate 25 (or the plate, the plate with non-uniform thickness or the object 1) may be a printed circuit board for hot-plugging at the connector 230 (the another connector 16), or the non-planar plate 25 (or the plate or the object 1) may be a printed circuit board for horizontally or vertically hot-plugging at the connector 230 (the another connector 16), or the non-planar plate 25 (or the plate, the plate with non-uniform thickness or the object 1) may be a printed circuit board for engaging or hot-plugging at the connector 230 (the another connector 16) by the elastic fastener 5, or the non-planar plate 25 (or the plate or the object 1) may be a printed circuit board for horizontally or vertically engaging or hot-plugging at the connector 230 (the another connector 16) by the elastic fastener 5, or the non-planar plate 25 (or the plate, the plate with non-uniform thickness or the object 1) is for engaging or hot-plugging at a connector 230 (the another connector 16) by the elastic fastener 5, or the non-planar plate 25 (or the plate, the plate with non-uniform thickness or the object 1) is for horizontally or vertically engaging or hot-plugging at a connector 230 (the another connector 16) by the elastic fastener 5, or the non-planar plate 25 (or the plate, the plate with non-uniform thickness or the object 1) is for engaging or hot-plugging at a connector 230 (the another connector 16) by the elastic fastener 5 and vertically or horizontally limiting by another fastener 5a, or the non-planar plate 25 (or the plate, the plate with non-uniform thickness or the object 1) is for horizontally or vertically engaging or hot-plugging at a connector 230 (the another connector 16) by the elastic fastener 5 and vertically or horizontally limiting by another fastener 5a, or the non-planar plate 25 (or the plate, the plate with non-uniform thickness or the object 1) is for engaging by the elastic fastener 5 and vertically or horizontally limiting by another fastener 5a, or the non-planar plate 25 (or the plate, the plate with non-uniform thickness or the object 1) is for horizontally or vertically engaging by the elastic fastener 5 and vertically or horizontally limiting by another fastener 5a, thereby enabling the present disclosure to better meet actual application requirements.

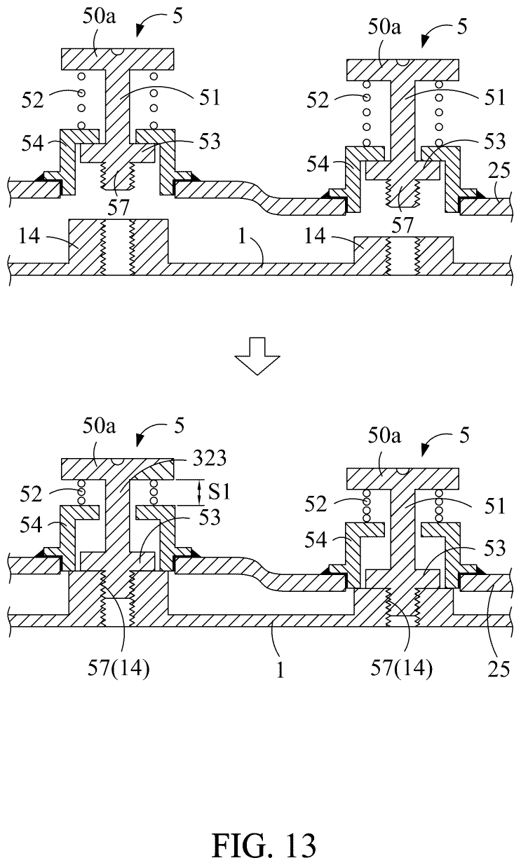

Referring to FIG. 1, FIG. 2, FIG. 13 and FIG. 14, another fixing structure 100 is provided according to an embodiment of the present disclosure. The fixing structure 100 includes a heat dissipating device 2, an object 1 and an elastic fastener 5.

The heat dissipating device 2 is provided with at least one non-planar plate 25 (which may be the flank 22 above, a plate or a plate with non-uniform thickness). The object 1 corresponds to the heat dissipating device 2 and is provided with at least one engaged portion 14. The elastic fastener 5 may be arranged at the non-planar plate 25 by the solder layer 95 and be engaged with the engaged portion 14. The elastic fastener 5 includes an operating head 50a, a rod 51 connected to the operating head 50a, a body 54 provided at the rod 51 and arranged at the non-planar plate 25, an elastic element 52 sleeving the rod 51, and an engaging portion 57 provided at the rod 51. By rotating the operating head 50a, the engaging portion 57 is engaged with the engaged portion 14 or the engaging portion 57 is disengaged from the engaged portion 14, and an elastic force is provided by the elastic element 52 to press the heat dissipating device 2 against the heat generating body 10 to dissipate heat. FIG. 13 and FIG. 14 show the non-planar plate 25 or a non-planar printed circuit board (or a plate with non-uniform thickness or a printed circuit board with non-uniform thickness).

In one embodiment, the elastic fastener 5 is provided with a stopping portion 53. The stopping portion 53 is for defining an elastic space S1 for the elastic fastener 5 to use the elastic space S1 to adjust an engaging height, thereby enabling the present disclosure to better meet actual application requirements.

In one embodiment, a distance (an elastic distance, or an elastic interval) between the operating head 50a and the non-planar plate 25 (or the plate, the plate with non-uniform thickness, or an engaged portion 14 of the object 1) may be pulled close (or elastically compressed, elastically pressed, or elastically separated), thereby enabling the present disclosure to better meet actual application requirements.

Referring to FIG. 15 to FIG. 17, in one embodiment, a difference from the embodiments above is that, the elastic fastener 5 is provided with another elastic element 3 and is further provided with a blocking portion 31, and the another elastic element 3 abuts between the blocking portion 31 and the body 54 (as shown by a, b, c and d in FIG. 15).

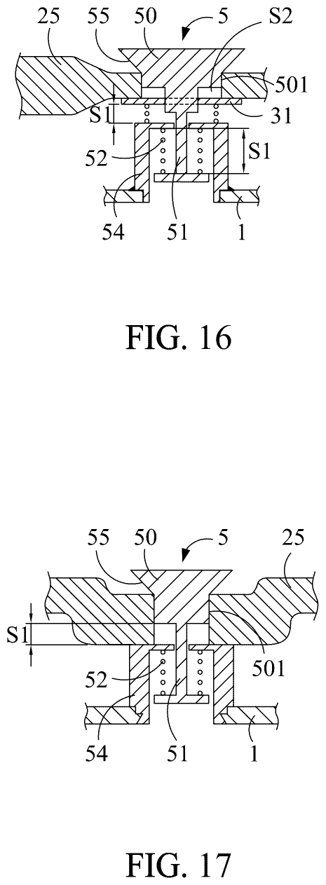

In one embodiment above, as shown in FIG. 16 and FIG. 17, the another elastic element 3 is for blocking against the non-planar plate 25 (or the plate, the plate with non-uniform thickness or the object 1), the another elastic element 3 is for blocking against or clamping at the non-planar plate 25 (or the plate, the plate with non-uniform thickness or the object 1) by the coupling head 50, and the another elastic element 3 is for blocking against the non-planar plate 25 (or the plate, the plate with non-uniform thickness or the object 1) by the blocking portion 31, or the another elastic element 3 is for blocking against or clamping at the non-planar plate 25 (or the plate, the plate with non-uniform thickness or the object 1) by the blocking portion 31 and the coupling head 50.

In one embodiment above, the blocking portion 31 is for generating a blocking space S2 (as shown in FIG. 16) when the coupling head 50 is engaged with the non-planar plate 25 (or the plate, the plate with non-uniform thickness or the object 1), wherein the blocking space S2 is generated by the coupling head 50 and the blocking portion 31 pressing against the non-planar plate 25 (or the plate, the plate with non-uniform thickness or the object 1), thereby enabling the present disclosure to better meet actual application requirements.

In one embodiment above, the coupling head 50 is provided with at least one step portion 501. The step portion 501 is for limiting, leaning against, clamping or pressing downward at the non-planar plate 25 (or the plate, the plate with non-uniform thickness or the object 1), thereby enabling the present disclosure to better meet actual application requirements.

In one embodiment above, the rod 51 and the body 54 of the elastic fastener 5 are movably combined, integrally formed, or fixedly combined, thereby enabling the present disclosure to better meet actual application requirements.

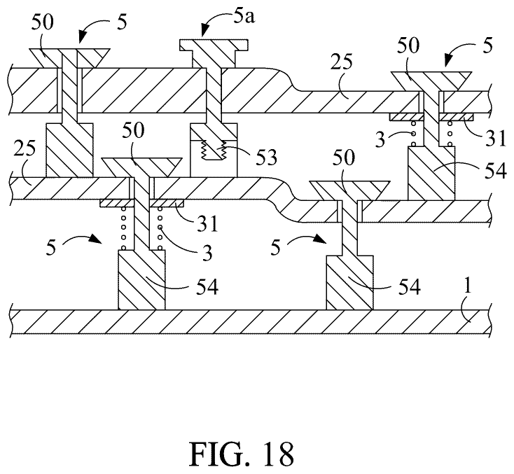

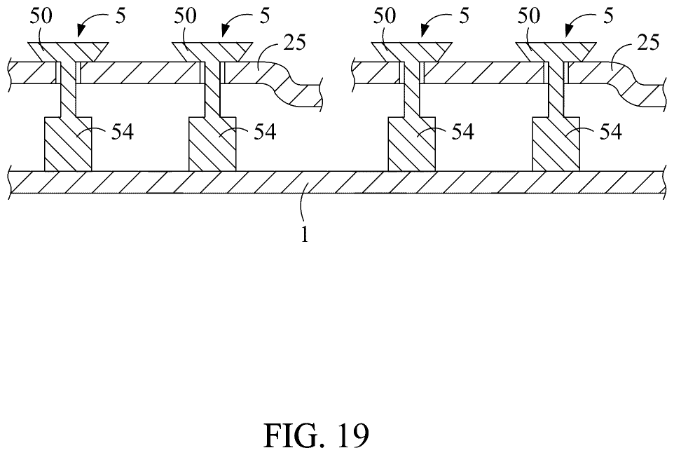

Referring to FIG. 18 and FIG. 19, in one embodiment, a difference from the embodiments above is that, the object 1 may be a non-planar plate (or a plate with non-uniform thickness) for engaging two non-planar plates 25 (or two plates with non-uniform thickness) with each other.

In one embodiment above, the object 1 (or the non-planar plate 25, the plate, the plate with non-uniform thickness, or the another object 24) is assembled with two or more non-planar plates 25, or wherein the two or more non-planar plates 25 are at top-down positions (as shown in FIG. 18) or horizontal positions (as shown in FIG. 19).

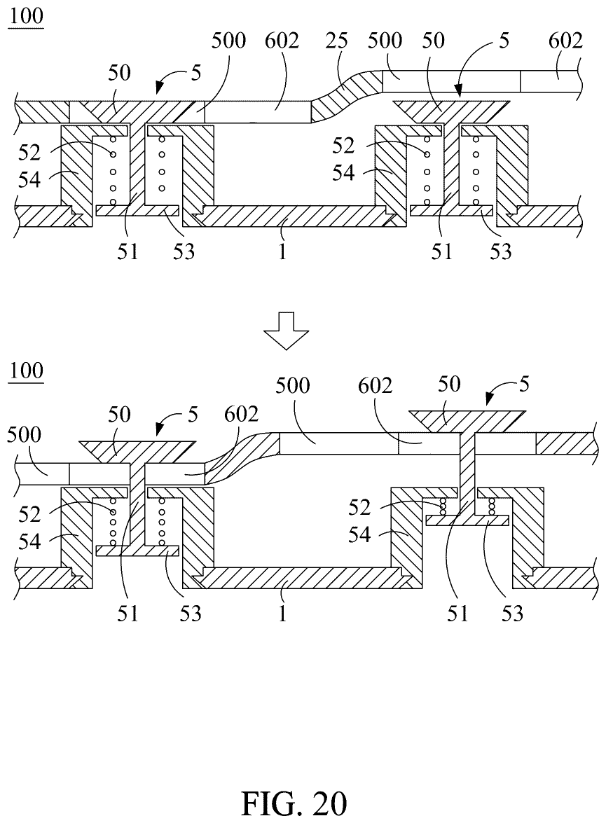

Referring to FIG. 20, another fixing structure 100 is provided according to an embodiment of the present disclosure. The fixing structure 100 includes a non-planar plate 25, an object 1 and at least one elastic fastener 5. The object 1 corresponds to the non-planar plate 25, and the elastic fastener 5 is arranged at the object 1 and is engaged with the non-planar plate 25.

In one embodiment, the elastic fastener 5 includes a coupling head 50, a rod 51 connected to the coupling head 50, a body 54 assembled at the rod 51 and arranged at the object 1, and an elastic element 52 provided at the rod 51, wherein the elastic element 52 abuts between a stopping portion 504 and the body 54.

In one embodiment, the non-planar plate 25 is provided with an entrance portion 500 and a slide portion 602, wherein the entrance portion 500 is in communication with the slide portion 602. The elastic fastener 5 enters the entrance portion 500 by the coupling head 50, and has the rod 51 enter the slide portion 602 to lean the coupling head 50 against the non-planar plate 25 and provide an elastic force of the elastic element 52 to tightly secure the coupling head 50 at the non-planar plate 25, thereby achieving the effect of quickly fixing the non-planar plate 25 and the object 1 in a labor-saving manner.

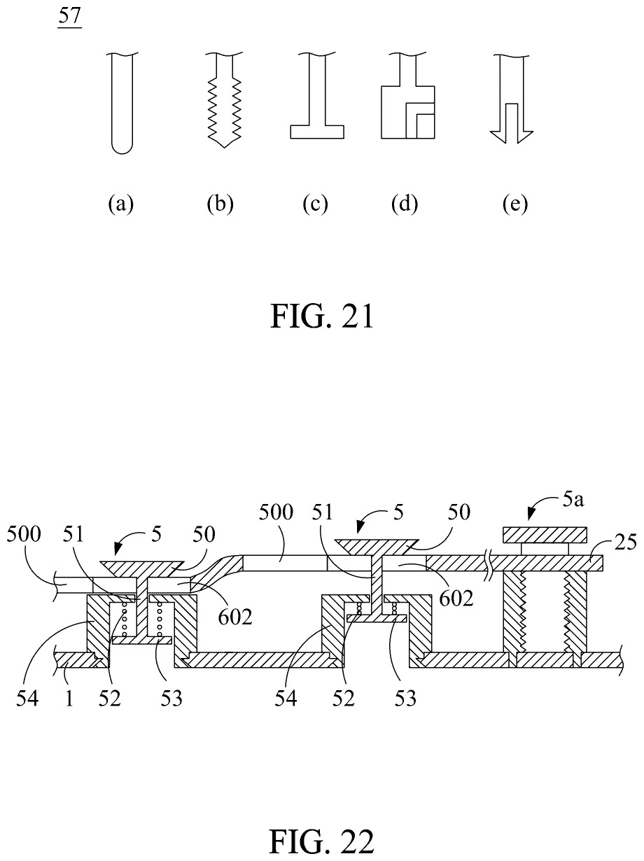

Referring to FIG. 21, as shown in the drawing, in addition to the embodiments above, in one embodiment of the present disclosure, a difference from the embodiments is that, the engaging portion 57 may also be a column (as part a shown in FIG. 21), a thread (as part b in FIG. 21), an outer fastener (as part c in FIG. 21), an inner fastener (as part d in FIG. 21) or an elastic fastener (as part e in FIG. 21), thereby enabling the engaging portion 57 of the present disclosure to better meet actual application requirements.

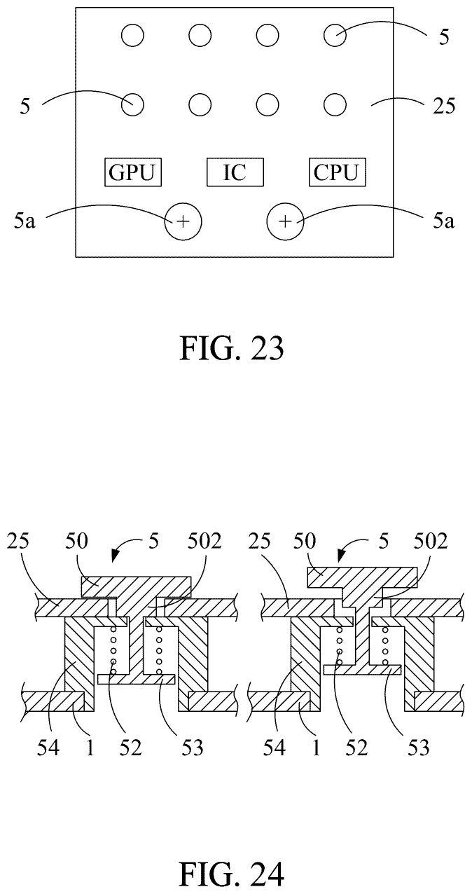

Referring to FIG. 22 and FIG. 23, as shown in the drawings, in addition to the embodiments above, in one embodiment of the present disclosure, a difference from the embodiments is that, at least one another fastener 33 may be included. In addition to engaging with the non-planar plate 25 by the elastic fastener 5, the another fastener 33 may be further used for horizontal positioning of the non-planar plate 25, or the another fastener 33 may be used for horizontal positioning after the non-planar plate 25 is first horizontally fitted by the elastic fastener 5, thereby enabling the present disclosure to better meet actual application requirements.

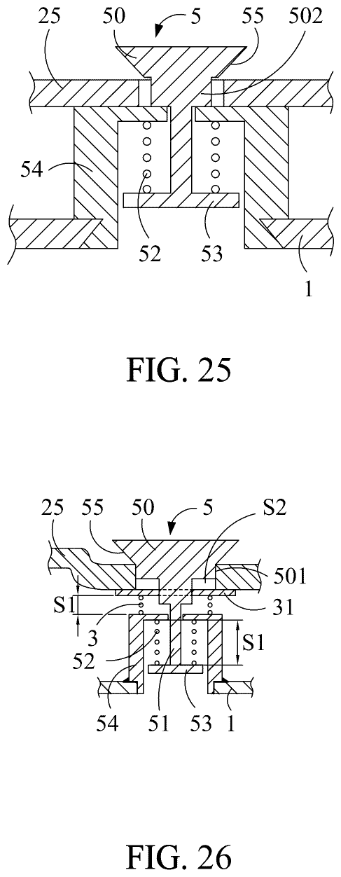

Referring to FIG. 24 and FIG. 25, as shown in the drawings, in addition to the embodiments above, in one embodiment of the present disclosure, a difference from the embodiments is that, the elastic fastener 5 is provided with a neck 502. The neck 502 is for engaging the non-planar plate 25 with different thicknesses (as shown in FIG. 24), and the coupling head 50 is provided with a guide surface 55 by which the non-planar plate 25 is guided for engaging (as shown in FIG. 25). Thus, the present disclosure is enabled to better meet actual application requirements.

Referring to FIG. 26, in addition to the embodiments above, in one embodiment of the present disclosure, a difference from the embodiments above is that, the elastic fastener 5 is provided with another elastic element 3 and is further provided with a blocking portion 31, wherein the another element 3 abuts between the blocking portion 31 and the body 54.

The present disclosure is described by way of the preferred embodiments above. A person skilled in the art should understand that, the embodiments are merely for illustrating the present disclosure and are not to be construed as limitations to the scope of the present disclosure. It should be noted that all equivalent changes, replacements and substitutions made to the embodiments are encompassed within the scope of the present disclosure. Therefore, the legal protection for the present disclosure should be defined by the appended claims.

What is claimed is:

1. A fixing structure, comprising:
at least one non-planar plate, a plate or a plate with non-uniform thickness, provided with at least one entrance portion, or a slide portion in communication with the entrance portion;
an object, corresponding to the non-planar plate, the plate or the plate with non-uniform thickness; and
an elastic fastener, arranged at the object, the elastic fastener comprising a coupling head, or a rod connected to the coupling head, or a body provided at the rod and arranged at the object, or an elastic element sleeving the rod, or an elastic element provided at the elastic fastener; or the elastic fastener being adapted to enter the slide portion by the coupling head via the entrance portion; or the elastic fastener being adapted to enter by the coupling head via the entrance portion, or lean the coupling head against the non-planar plate, a plate or a plate with non-uniform thickness, or provide an elastic force for tightly securing the coupling head at the non-planar plate, a plate or a plate with non-uniform thickness by the elastic element, or provide an elastic space by the coupling head, or pull close a distance between an operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

2. A fixing structure, comprising:
at least one non-planar plate, a plate or a plate with non-uniform thickness;
an object, corresponding to the non-planar plate, a plate or a plate with non-uniform thickness, the object provided with at least one engaged portion; and
an elastic fastener, arranged at the non-planar plate, the plate or the plate with non-uniform thickness, and engaged with the engaged portion; or the elastic fastener comprising an operating head or a coupling head, or a rod connected to the operating head or the coupling head, or a body provided at the rod or arranged at the non-planar plate, the plate, the plate with non-uniform thickness or the object, or an elastic element sleeving the rod, or an elastic element provided at the elastic fastener, or an engaging portion provided at the rod; or the operating head being rotated to engage the engaging portion with the engaged portion or to disengage the engaging portion from the engaged portion, or provide an elastic extension and retraction space, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

3. A fixing structure, comprising:
at least one non-planar plate, a plate or a plate with non-uniform thickness;
an object, corresponding to the non-planar plate, the plate or the plate with non-uniform thickness; and
an elastic fastener, arranged at the object, the elastic fastener comprising a coupling head, or a rod connected to the coupling head, or a body provided at the rod and arranged at the object, or an elastic element sleeving the rod, or an elastic element provided at the elastic fastener; or the elastic fastener being adapted to lean the coupling head against the non-planar plate, a plate or a plate with non-uniform thickness, or provide an elastic force for tightly securing the coupling head at the non-planar plate, a plate or a plate with non-uniform thickness by the elastic element, or provide an elastic space by the coupling head, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

4. The fixing structure according to claim 1, wherein the non-planar plate, the plate, the plate with non-uniform thickness or the object is a printed circuit board, a metal plate, a heat dissipating device, a heat dissipating body, an electronic element, a metal body, a plastic body, a non-metal body, a casing, an electronic device, an integrated circuit, a plastic plate or a non-metal plate, or the non-planar plate, the plate, the plate with non-uniform thickness or the object is provided at a heat dissipating device, a heat dissipating body, a printed circuit board, an electronic element, an integrated circuit, a metal body, a plastic body, a non-metal body, a casing or an electronic device.

5. The fixing structure according to claim 2, wherein the non-planar plate, the plate, the plate with non-uniform thickness or the object is a printed circuit board, a metal plate, a heat dissipating device, a heat dissipating body, an electronic element, a metal body, a plastic body, a non-metal body, a casing, an electronic device, an integrated circuit, a plastic plate or a non-metal plate, or the non-planar plate, the plate, the plate with non-uniform thickness or the object is provided at a heat dissipating device, a heat dissipating body, a printed circuit board, an electronic element, an integrated circuit, a metal body, a plastic body, a non-metal body, a casing or an electronic device.

6. The fixing structure according to claim 3, wherein the non-planar plate, the plate, the plate with non-uniform thickness or the object is a printed circuit board, a metal plate, a heat dissipating device, a heat dissipating body, an electronic element, a metal body, a plastic body, a non-metal body, a casing, an electronic device, an integrated circuit, a plastic plate or a non-metal plate, or the non-planar plate, the plate, the plate with non-uniform thickness or the object is provided at a heat dissipating device, a heat dissipating body, a printed circuit board, an electronic element, an integrated circuit, a metal body, a plastic body, a non-metal body, a casing or an electronic device.

7. The fixing structure according to claim 1, wherein elastic fastener is provided with a stopping portion, the stopping portion is for defining the elastic space for the elastic fastener to use the elastic space to adjust an engaging height; or the elastic fastener is adapted to laterally or vertically fit into the non-planar plate, the plate, the plate with non-uniform thickness or the object; or the rod and the body of the elastic fastener are movably combined, integrally formed or fixedly combined; or the elastic fastener is provided with a blocking portion, and the blocking portion is for generating a blocking space when the coupling head is engaged with the non-planar plate, the plate, the plate with non-uniform thickness or the object; or the blocking space is generated by the coupling head and the blocking portion pressing against the non-planar plate, the plate, the plate with non-uniform thickness or the object.

8. The fixing structure according to claim 2, wherein elastic fastener is provided with a stopping portion, the stopping portion is for defining the elastic space for the elastic fastener to use the elastic space to adjust an engaging height; or the elastic fastener is adapted to laterally or vertically fit into the non-planar plate, the plate, the plate with non-uniform thickness or the object; or the rod and the body of the elastic fastener are movably combined, integrally formed or fixedly combined; or the elastic fastener is provided with a blocking portion, and the blocking portion is for generating a blocking space when the coupling head is engaged with the non-planar plate, the plate, the plate with non-uniform thickness or the object; or the blocking space is generated by the coupling head and the blocking portion pressing against the non-planar plate, the plate, the plate with non-uniform thickness or the object.

9. The fixing structure according to claim 3, wherein elastic fastener is provided with a stopping portion, the stopping portion is for defining the elastic space for the elastic fastener to use the elastic space to adjust an engaging height; or the elastic fastener is adapted to laterally or vertically fit into the non-planar plate, the plate, the plate with non-uniform thickness or the object; or the rod and the body of the elastic fastener are movably combined, integrally formed or fixedly combined; or the elastic fastener is provided with a blocking portion, and the blocking portion is for generating a blocking space when the coupling head is engaged with the non-planar plate, the plate, the plate with non-uniform thickness or the object; or the blocking space is generated by the coupling head and the blocking portion pressing against the non-planar plate, the plate, the plate with non-uniform thickness or the object.

10. The fixing structure according to claim 1, wherein the coupling head has a guide surface, which is for guiding the coupling head to move upward onto the slide portion when the rod enters the entrance portion or the slide portion; or the coupling head is provided with at least one step portion, which is for limiting, leaning against, clamping or pressing downward at the non-planar plate, the plate, the plate with non-uniform thickness or the object.

11. The fixing structure according to claim 2, wherein the coupling head has a guide surface, which is for guiding the coupling head to move upward onto the slide portion when the rod enters the entrance portion or the slide portion; or the coupling head is provided with at least one step portion, which is for limiting, leaning against, clamping or pressing downward at the non-planar plate, the plate, the plate with non-uniform thickness or the object.

12. The fixing structure according to claim 3, wherein the coupling head has a guide surface, which is for guiding the coupling head to move upward onto the slide portion when the rod enters the entrance portion or the slide portion; or the coupling head is provided with at least one step portion, which is for limiting, leaning against, clamping or pressing downward at the non-planar plate, the plate, the plate with non-uniform thickness or the object.

13. The fixing structure according to claim 1, wherein a printed circuit board having a connector is plugged into the object, the non-planar plate, the plate, the plate with non-uniform thickness or the object or another connector of another object; or the elastic fastener is for engaging the non-planar plate, the plate, the plate with non-uniform thickness or the another object with the object; or wherein the elastic fastener is a coupling head, a thread, a column, an outer fastener, an inner fastener or an elastic fastening body; or the elastic fastener is engagement connected, rivet connected, expansion connected, weld connected or lock connected to the non-planar plate, the plate, the plate with non-uniform thickness or the object; or the elastic fastener and the non-planar plate, the plate, the plate with non-uniform thickness or the object are formed integrally.

14. The fixing structure according to claim 2, wherein a printed circuit board having a connector is plugged into the object, the non-planar plate, the plate, the plate with non-uniform thickness or the object or another connector of another object; or the elastic fastener is for engaging the non-planar plate, the plate, the plate with non-uniform thickness or the another object with the object; or wherein the elastic fastener is a coupling head, a thread, a column, an outer fastener, an inner fastener or an elastic fastening body; or the elastic fastener is engagement connected, rivet connected, expansion connected, weld connected or lock connected to the non-planar plate, the plate, the plate with non-uniform thickness or the object; or the elastic fastener and the non-planar plate, the plate, the plate with non-uniform thickness or the object are formed integrally.

15. The fixing structure according to claim 3, wherein a printed circuit board having a connector is plugged into the object, the non-planar plate, the plate, the plate with non-uniform thickness or the object or another connector of another object; or the elastic fastener is for engaging the non-planar plate, the plate, the plate with non-uniform thickness or the another object with the object; or wherein the elastic fastener is a coupling head, a thread, a column, an outer fastener, an inner fastener or an elastic fastening body; or the elastic fastener is engagement connected, rivet connected, expansion connected, weld connected or lock connected to the non-planar plate, the plate, the plate with non-uniform thickness or the object; or the elastic fastener and the non-planar plate, the plate, the plate with non-uniform thickness or the object are formed integrally.

16. The fixing structure according to claim 1, wherein the non-planar plate, the plate or the plate with non-uniform thickness is heated at a high temperature and deforms into a non-planar plate or a plate with non-uniform thickness; or the non-planar plate, the plate or the plate with non-uniform thickness is heated at a high temperature and cooled and deforms into a non-planar plate or a plate with non-uniform thickness; or the non-planar plate, the plate or the plate with non-uniform thickness is heated at a high temperature and cooled and deforms into a non-planar printed circuit board or a printed circuit board with non-uniform thickness; or the non-planar plate, the plate or the plate with non-uniform thickness is heated at a high temperature and deforms into a non-planar printed circuit board or a printed circuit board with non-uniform thickness.

17. The fixing structure according to claim 2, wherein the non-planar plate, the plate or the plate with non-uniform thickness is heated at a high temperature and deforms into a non-planar plate or a plate with non-uniform thickness; or the non-planar plate, the plate or the plate with non-uniform thickness is heated at a high temperature and cooled and deforms into a non-planar plate or a plate with non-uniform thickness; or the non-planar plate, the plate or the plate with non-uniform thickness is heated at a high temperature and cooled and deforms into a non-planar printed circuit board or a printed circuit board with non-uniform thickness; or the non-planar plate, the plate or the plate with non-uniform thickness is heated at a high temperature and deforms into a non-planar printed circuit board or a printed circuit board with non-uniform thickness.

18. The fixing structure according to claim 3, wherein the non-planar plate, the plate or the plate with non-uniform thickness is heated at a high temperature and deforms into a non-planar plate or a plate with non-uniform thickness; or the non-planar plate, the plate or the plate with non-uniform thickness is heated at a high temperature and cooled and deforms into a non-planar plate or a plate with non-uniform thickness; or the non-planar plate, the plate or the plate with non-uniform thickness is heated at a high temperature and cooled and deforms into a non-planar printed circuit board or a printed circuit board with non-uniform thickness; or the non-planar plate, the plate or the plate with non-uniform thickness is heated at a high temperature and deforms into a non-planar printed circuit board or a printed circuit board with non-uniform thickness.

19. The fixing structure according to claim 1, wherein the non-planar plate, the plate, the plate with non-uniform thickness or the object is a printed circuit board for hot-plugging at a connector; or the non-planar plate, the plate, the plate with non-uniform thickness or the object is a printed circuit board for horizontally or vertically hot-plugging at a connector; or the non-planar plate, the plate, the plate with non-uniform thickness or the object is a printed circuit board for engaging with or hot-plugging at a connector by the elastic fastener; or the non-planar plate, the plate, the plate with non-uniform thickness or the object is a printed circuit board for horizontally or vertically engaging with or hot-plugging at a connector by the elastic fastener; or the non-planar plate, the plate, the plate with non-uniform thickness or the object is for engaging with or hot-plugging at a connector by the elastic fastener; or the non-planar plate, the plate, the plate with non-uniform thickness or the object is for horizontally or vertically engaging with or hot-plugging at a connector by the elastic fastener; or the non-planar plate, the plate, the plate with non-uniform thickness or the object is for engaging with or hot-plugging at a connector by the elastic fastener and vertically or horizontally limiting by another fastener; or the non-planar plate, the plate, the plate with non-uniform thickness or the object is for horizontally or vertically engaging with or hot-plugging at a connector by the elastic fastener and vertically or horizontally limiting by another fastener; or the non-planar plate, the plate, the plate with non-uniform thickness or the object is for engaging by the elastic fastener and vertically or horizontally limiting by another fastener; or the non-planar plate, the plate, the plate with non-uniform thickness or the object is for horizontally or vertically engaging by the elastic fastener and vertically or horizontally limiting by another fastener.

20. The fixing structure according to claim 2, wherein the non-planar plate, the plate, the plate with non-uniform thickness or the object is a printed circuit board for hot-plugging at a connector; or the non-planar plate, the plate, the plate with non-uniform thickness or the object is a printed circuit board for horizontally or vertically hot-plugging at a connector; or the non-planar plate, the plate, the plate with non-uniform thickness or the object is a printed circuit board for engaging with or hot-plugging at a connector by the elastic fastener; or the non-planar plate, the plate, the plate with non-uniform thickness or the object is a printed circuit board for horizontally or vertically engaging with or hot-plugging at a connector by the elastic fastener; or the non-planar plate, the plate, the plate with non-uniform thickness or the object is for engaging with or hot-plugging at a connector by the elastic fastener; or the non-planar plate, the plate, the plate with non-uniform thickness or the object is for horizontally or vertically engaging with or hot-plugging at a connector by the elastic fastener; or the non-planar plate, the plate, the plate with non-uniform thickness or the object is for engaging with or hot-plugging at a connector by the elastic fastener and vertically or horizontally limiting by another fastener; or the non-planar plate, the plate, the plate with non-uniform thickness or the object is for horizontally or vertically engaging with or hot-plugging at a connector by the elastic fastener and vertically or horizontally limiting by another fastener; or the non-planar plate, the plate, the plate with non-uniform thickness or the object is for engaging by the elastic fastener and vertically or horizontally limiting by another fastener; or the non-planar plate, the plate, the plate with non-uniform thickness or the object is for horizontally or vertically engaging by the elastic fastener and vertically or horizontally limiting by another fastener.

21. The fixing structure according to claim 3, wherein the non-planar plate, the plate, the plate with non-uniform thickness or the object is a printed circuit board for hot-plugging at a connector; or the non-planar plate, the plate, the plate with non-uniform thickness or the object is a printed circuit board for horizontally or vertically hot-plugging at a connector; or the non-planar plate, the plate, the plate with non-uniform thickness or the object is a printed circuit board for engaging with or hot-plugging at a connector by the elastic fastener; or the non-planar plate, the plate, the plate with non-uniform thickness or the object is a printed circuit board for horizontally or vertically engaging with or hot-plugging at a connector by the elastic fastener; or the non-planar plate, the plate, the plate with non-uniform thickness or the object is for engaging with or hot-plugging at a connector by the elastic fastener; or the non-planar plate, the plate, the plate with non-uniform thickness or the object is for horizontally or vertically engaging with or hot-plugging at a connector by the elastic fastener; or the non-planar plate, the plate, the plate with non-uniform thickness or the object is for engaging with or hot-plugging at a connector by the elastic fastener and vertically or horizontally limiting by another fastener; or the non-planar plate, the plate, the plate with non-uniform thickness or the object is for horizontally or vertically engaging with or hot-plugging at a connector by the elastic fastener and vertically or horizontally limiting by another fastener; or the non-planar plate, the plate, the plate with non-uniform thickness or the object is for engaging by the elastic fastener and vertically or horizontally limiting by another fastener; or the non-planar plate, the plate, the plate with non-uniform thickness or the object is for horizontally or vertically engaging by the elastic fastener and vertically or horizontally limiting by another fastener.

22. The fixing structure according to claim 1, wherein the object is a non-planar plate or plate with non-uniform thickness to engage two non-planar plates or two plates with non-uniform thickness with each other; or the non-planar plate, the plate, the plate with non-uniform thickness, the object or another object assembles two or more non-planar plates; or wherein two or more non-planar plates are at top-down positions or horizontal positions.

23. The fixing structure according to claim 2, wherein the object is a non-planar plate or plate with non-uniform thickness to engage two non-planar plates or two plates with non-uniform thickness with each other; or the non-planar plate, the plate, the plate with non-uniform thickness, the object or another object assembles two or more non-planar plates; or wherein two or more non-planar plates are at top-down positions or horizontal positions.

24. The fixing structure according to claim 3, wherein the object is a non-planar plate or plate with non-uniform thickness to engage two non-planar plates or two plates with non-uniform thickness with each other; or the non-planar plate, the plate, the plate with non-uniform thickness, the object or another object assembles two or more non-planar plates; or wherein two or more non-planar plates are at top-down positions or horizontal positions.

25. The fixing structure according to claim 1, wherein the elastic fastener is provided with another elastic element, and the another elastic element is for blocking against the non-planar plate, the plate, the plate with non-uniform thickness or the object; or the another elastic element is for blocking against or clamping at the non-planar plate, the plate, the plate with non-uniform thickness or the object by the coupling head; or the another elastic element is for blocking against the non-planar plate or the object by a blocking portion; or the another elastic element is for blocking against or clamping at the non-planar plate, the plate, the plate with non-uniform thickness or the object by a blocking portion and the coupling head.

26. The fixing structure according to claim 2, wherein the elastic fastener is provided with another elastic element, and the another elastic element is for blocking against the non-planar plate, the plate, the plate with non-uniform thickness or the object; or the another elastic element is for blocking against or clamping at the non-planar plate, the plate, the plate with non-uniform thickness or the object by the coupling head; or the another elastic element is for blocking against the non-planar plate or the object by a blocking portion; or the another elastic element is for blocking against or clamping at the non-planar plate, the plate, the plate with non-uniform thickness or the object by a blocking portion and the coupling head.

27. The fixing structure according to claim 3, wherein the elastic fastener is provided with another elastic element, and the another elastic element is for blocking against the non-planar plate, the plate, the plate with non-uniform thickness or the object; or the another elastic element is for blocking against or clamping at the non-planar plate, the plate, the plate with non-uniform thickness or the object by the coupling head; or the another elastic element is for blocking against the non-planar plate or the object by a blocking portion; or the another elastic element is for blocking against or clamping at the non-planar plate, the plate, the plate with non-uniform thickness or the object by a blocking portion and the coupling head.

28. A fixing structure, comprising: an elastic fastener, the elastic fastener being adapted to enter a slide portion by a coupling head via an entrance portion, or the elastic fastener being adapted to enter by a coupling head via an entrance portion, or lean the coupling head against a non-planar plate, a plate, a plate with non-uniform thickness or an object, or provide an elastic force for tightly securing the coupling head at the non-planar plate, the plate, the plate with non-uniform thickness or the object by an elastic element, or provide an elastic space by the coupling head, or pull close a distance between an operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

29. A fixing structure, comprising: an elastic fastener, the elastic fastener having an operating head, or wherein the operating head is rotated to engage an engaging portion with an engaged portion of a non-planar plate, a plate, a plate with non-uniform thickness or an object, or to disengage the engaging portion from the engaged portion, or the elastic fastener being adapted to enter a non-planar plate, a plate or a plate with non-uniform thickness via an entrance portion, or the elastic fastener being adapted to enter a non-planar plate, a plate or a plate with non-uniform thickness via an entrance portion or a slide portion, or the elastic fastener being adapted to provide an elastic extension and retraction space by the elastic fastener, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.

30. A fixing structure, comprising: an elastic fastener, the elastic fastener being adapted to lean against a non-planar plate, a plate, a plate with non-uniform thickness or an object by a coupling head, or provide an elastic force for tightly securing the coupling head at the non-planar plate, the plate, the plate with non-uniform thickness or the object by an elastic element, or provide an elastic space by the coupling head, or pull close a distance between the operating head and an engaged portion of a non-planar plate, a plate, a plate with non-uniform thickness or an object, or elastically compress, elastically press or elastically separate a distance, an elastic distance or an elastic interval between the operating head and an engaged portion of a non-planar plate, a plate, a plate with non-uniform thickness or an object.
